(19) United States
(12) Patent Application Publication
(10) Pub. No.: US 2011/0101301 A1
(43) Pub. Date: May 5, 2011

(54) LIGHT EMITTING DEVICE WITH A COUPLED QUANTUM WELL STRUCTURE

(75) Inventors: You-Da Lin, Goleta, CA (US); Arpan Chakraborty, Goleta, CA (US); Shuji Nakamura, Santa Barbara, CA (US); Steven P. DenBaars, Goleta, CA (US)

(73) Assignee: THE REGENTS OF THE UNIVERSITY OF CALIFORNIA, Oakland, CA (US)

(21) Appl. No.: 12/916,218

(22) Filed: Oct. 29, 2010

Related U.S. Application Data
(60) Provisional application No. 61/258,158, filed on Nov. 4, 2009.

(51) Int. Cl. H01L 33/06

(52) U.S. Cl. 257/13; 438/47; 257/E33.008

(57) ABSTRACT

A light emitting device with a coupled quantum well structure in an active region. The coupled quantum well structure may include two or more wells are separated by one or more mini-barriers, and the wells and mini-barriers together are sandwiched by barriers. The coupled quantum well structure provides almost the same effect as a wide quantum well, due to the coupling of the wavefunctions through the mini-barrier. The light emitting device may be a nonpolar, semipolar or polar (Al,Ga,In)N based light emitting device.

### CROSS-REFERENCE TO RELATED APPLICATIONS

This application claims the benefit under 35 U.S.C. Section 119(e) of co-pending and commonly assigned U.S. Provisional Patent Application Ser. No. 61/258,158, filed on Nov. 4, 2009, by You-Da Lin, Arpan Chakraborty, Shuji Nakamura, and Steven P. DenBaars, entitled “LIGHT EMITTING DEVICE WITH COUPLED QUANTUM WELLS,” attorney's docket number 30794.339-US-P1 (2010-274-1), which application is incorporated by reference herein.

This application is related to co-pending and commonly-assigned U.S. Utility patent application Ser. No. 12/901,838, filed on Oct. 11, 2010, by Arpan Chakraborty, You-Da Lin, Shuji Nakamura, and Steven P. DenBaars, entitled “LIGHT EMITTING DEVICE WITH A STAIR QUANTUM WELL STRUCTURE” attorney's docket number 30794.321-US-U1 (2009-796-2), which application claims the benefit under 35 U.S.C. Section 119(e) of co-pending and commonly assigned U.S. Provisional Patent Application Ser. No. 61/250,391, filed on Oct. 9, 2009, by Arpan Chakraborty, You-Da Lin, Shuji Nakamura, and Steven P. DenBaars, entitled “LIGHT EMITTING DEVICE WITH STAIR QUANTUM WELL” attorney's docket number 30794.321-US-P1 (2009-796-1), both of which applications are incorporated by reference herein.

### STATEMENT REGARDING FEDERALLY SPONSORED RESEARCH AND DEVELOPMENT

This invention was made with Government support under Grant No. FA8718-08-C-0005 awarded by DARPA-VIGIL. The Government has certain rights in this invention.

### BACKGROUND OF THE INVENTION

1. Field of the Invention

This invention relates to a light-emitting device with coupled quantum wells.

2. Description of the Related Art

A quantum well is a potential well that confines particles, which were originally free to move in three dimensions, to two dimensions, forcing them to occupy a planar region. Quantum wells are formed of semiconductor materials by having a quantum well layer with a lower band-gap sandwiched between two barrier layers with a higher or wider bandgap.

A quantum well structure can be illustrated by a graph of its potential energy function, which is the potential energy profile (eV) as a function of position, distance, or thickness (x). As described in more detail below, in such a graph, a horizontal line in the energy diagram indicates no change in the composition of the quantum well structure, a vertical line in the energy diagram indicates a discrete or abrupt change in the composition of the quantum well structure, and a sloping line in the energy diagram indicates a graded change in the composition of the quantum well structure.

With this in mind, three basic quantum well structures used in (Al,Ga,In)N light emitting devices can be described using such graphs:

1. FIG. 1 schematically illustrates a square quantum well structure, by means of a graph of the potential energy function for the structure. In FIG. 1, the vertical lines in the energy diagram on both the left and right sides of the quantum well 100 indicate that there are abrupt changes in composition at the interfaces between the quantum well 100 and the first and second barrier layers 102a, 102b, respectively.

2. FIG. 2(a) and FIG. 2(b) schematically illustrate a triangular quantum well structure, by means of graphs of the potential energy function. In FIG. 2(a), the sloping line in the energy diagram on the left side of the quantum well 200 indicates that there is a graded interface between the quantum well 200 and the first barrier layer 202a, while the vertical line in the energy diagram on the right side of the quantum well 200 indicates that there is an abrupt interface between the quantum well 200 and the second barrier layer 202b. Conversely, in FIG. 2(b), the sloping line in the energy diagram on the right side of the quantum well 200 indicates that there is a graded interface between the quantum well 200 and the second barrier layer 202b, while the vertical line in the energy diagram on the left side of the quantum well 200 indicates that there is an abrupt interface between the quantum well 200 and the first barrier layer 202a.

3. FIG. 3(a) and FIG. 3(b) schematically illustrate a quantum well structure that combines 1 and 2 above. In FIGS. 3(a) and 3(b), the quantum well 300 has a sloping line in the energy diagram, which indicates that the quantum well 300 itself has a graded composition, while the interfaces with the barrier layers 302a, 302b have vertical lines in the energy diagram, which indicates an abrupt change in composition at the interface between the quantum well 300 and the barrier layers 302a, 302b.

The problem with these structures, however, is that, due to the difference in material properties, for example, lattice mismatch, coefficient of thermal expansion (CTE) mismatch, etc., extended defects such as misfit dislocations are created at the well-barrier interface as a strain/stress relaxation mechanism. This effect is more dominant in nonpolar and semipolar III-nitrides because of in-plane anisotropy of the lattice (as shown in the micrograph of FIG. 4). The defects act as a non-radiative recombination center, resulting in a lowering of internal quantum efficiency (IQE) and adversely affecting device reliability.

Furthermore, it is difficult to grow thick InGaN wells of high In composition, required for green quantum wells, because of strain and InGaN segregation. Thicker wells are desired for long wavelength emission because of reduced quantum confinement, resulting in longer wavelength emission for a particular In composition. In c-plane devices, a single thick quantum is undesirable because of the enhanced quantum confined stark effect (QCSE) resulting in reduction of the overlap of electron and hole wavefunctions. However, in nonpolar and semipolar (Al,Ga,In)N quantum well structures, where QCSE is absent or reduced, growing thicker QWs is desirable for longer wavelength light emitting devices.

Thus, there is a need in the art for improved quantum well designs. The present invention satisfies this need.

### SUMMARY OF THE INVENTION

To overcome the limitations in the prior art described above, and to overcome other limitations that will become apparent upon reading and understanding the present specification, the present invention describes a coupled quantum well design in an active region of a light emitting device, wherein two or more wells are separated by one or more mini-barriers. By implementing a coupled quantum well structure, in a nonpolar (Al,Ga,In)N based light emitting device, for example, the problems described above may be alleviated, without affecting the quantum confinement to a large extent. A coupled quantum well structure provides almost the same effect as a wide quantum well, due to the coupling of the wavefunctions through the mini-barrier. The emission wavelength and the recombination efficiency can be tuned by varying the height and width of the mini-barrier.

Specifically, the present invention describes a light emitting device and a method for fabricating the light emitting device, comprising fabricating an (Al,Ga,In)N based active region including at least one coupled quantum well structure formed by at least one (Al,Ga,In)N based quantum well layer sandwiched between at least first and second (Al,Ga,In)N based barrier layers; wherein the coupled quantum well structure has a material composition that creates an energy diagram comprising: (1) at least two potential wells bounded by potential barriers, and (2) at least one potential mini-barrier between the two potential wells. The potential well is different from the potential mini-barrier, and the potential barriers are different from both the potential well and the potential mini-barriers.

In one embodiment, the coupled quantum well structure has a material composition that creates an energy diagram comprising: (i) a first one of the potential barriers; (ii) a first one of the potential wells; (iii) a first one of the potential mini-barriers; (iv) a second one of the potential wells; and (v) a second one of the potential barriers. In addition, the coupled quantum well structure may have a material composition that creates an energy diagram further comprising: a second one of the potential mini-barriers and a third one of the potential wells, positioned between the second one of the potential wells and the second one of the potential barriers. The coupled quantum well structure may also have a material composition that creates an energy diagram further comprising: a second one of the potential mini-barriers and a third one of the potential wells, positioned between the first one of the potential barriers and the first one of the potential wells.

In one embodiment, the material composition of the potential well is InₓGa₁₋ₓN, and the material composition of the potential mini-barrier is In_{y}Ga_{1-y}N, where y<x. In addition, the material composition of the potential barriers may be AlGaN, GaN, AlInGaN or In_{z}Ga_{1-z}N where z<y. Moreover, the material composition may comprise a polar, nonpolar or semipolar (Al,Ga,In)N based material composition.

### BRIEF DESCRIPTION OF THE DRAWINGS

Referring now to the drawings in which like reference numbers represent corresponding parts throughout:

FIGS. 1, 2(a), 2(b), 3(a) and 3(b) are schematic illustrations of quantum well structures comprising graphs of the potential energy function for the structures.

FIG. 4 is a micrograph of a multiple quantum well (MQW) structure.

FIG. 5 is a flowchart describing the process steps for fabrication of a nonpolar, semipolar or polar (Al,Ga,In)N light emitting device according to the preferred embodiment of the present invention.

FIG. 6 is a schematic cross-section of a light emitting device fabricated in FIG. 5 according to the preferred embodiment of the present invention.

FIGS. 7(a), 7(b) and 7(c) are schematic illustrations of coupled quantum well structures according to the present invention comprising graphs of the potential energy function for the structures, wherein the structures have a mini-barrier coupling two wells, the mini-barrier is an energy barrier coupling or in between the two wells, and FIG. 7(c) shows that the bandgap of the two wells connected by the mini-barrier is different.

FIGS. 8(a), 8(b) and 8(c) are schematic illustrations of a coupled quantum well structure according to the present invention comprising graphs of the potential energy function for the structure, wherein the structure has three wells and two mini-barriers for coupling the three wells, the mini-barrier is an energy barrier separating each well from another coupled well, and FIG. 8(c) shows graded quantum wells coupled by a mini-barrier and having a different direction of grading.

FIGS. 9(a) and 9(b) are schematic illustrations of coupled quantum well structures according to the present invention comprising graphs of the potential energy function for the structures, wherein the structures have coupled triangular quantum wells.

FIGS. 10(a) and 10(b) are graphs showing the ineffectiveness of coupled quantum well structures in the polar (Al,Ga,In)N materials system, according to the present invention, wherein FIG. 10(a) shows the energy band diagram of a quantum well structure, and FIG. 10(b) shows the electron wavefunction in the polar coupled quantum well system shown in FIG. 8(a).

FIGS. 11(a) and 11(b) are graphs showing the effectiveness of coupled quantum well structures in the nonpolar (Al,Ga,In)N materials system, according to the present invention, wherein FIG. 11(a) shows the energy band diagram of a quantum well structure, and FIG. 11(b) shows the electron wavefunction in the nonpolar coupled quantum well system shown in FIG. 11(a).

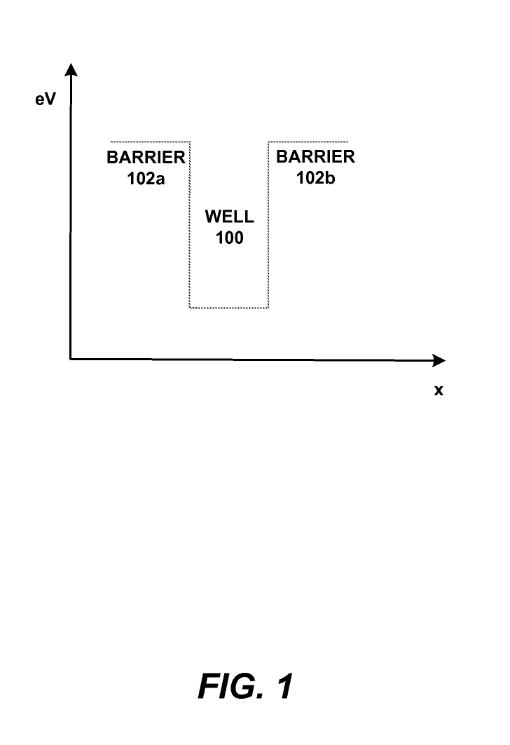

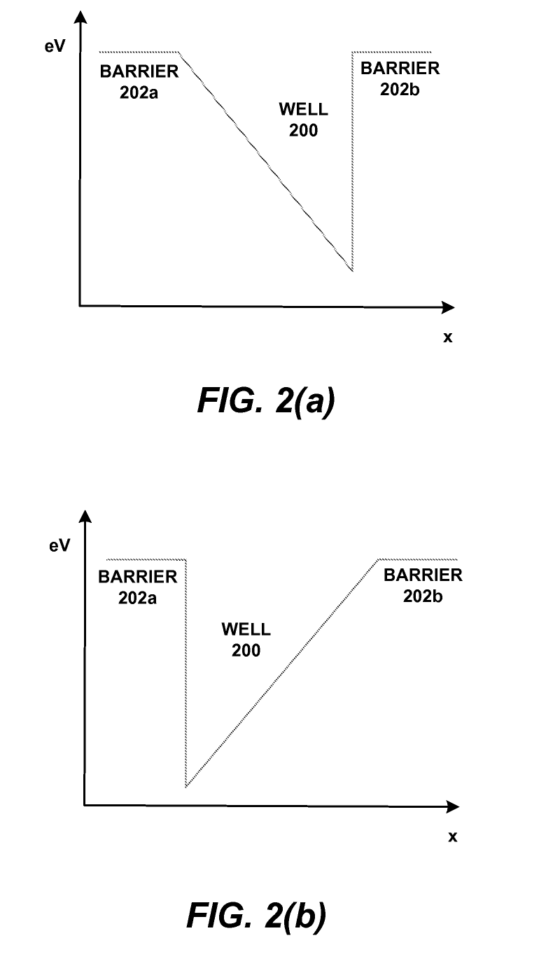

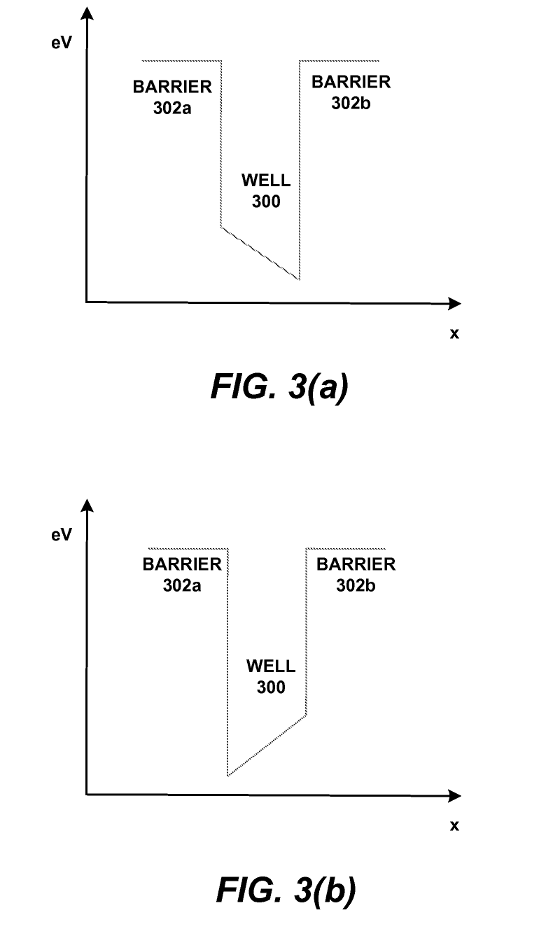

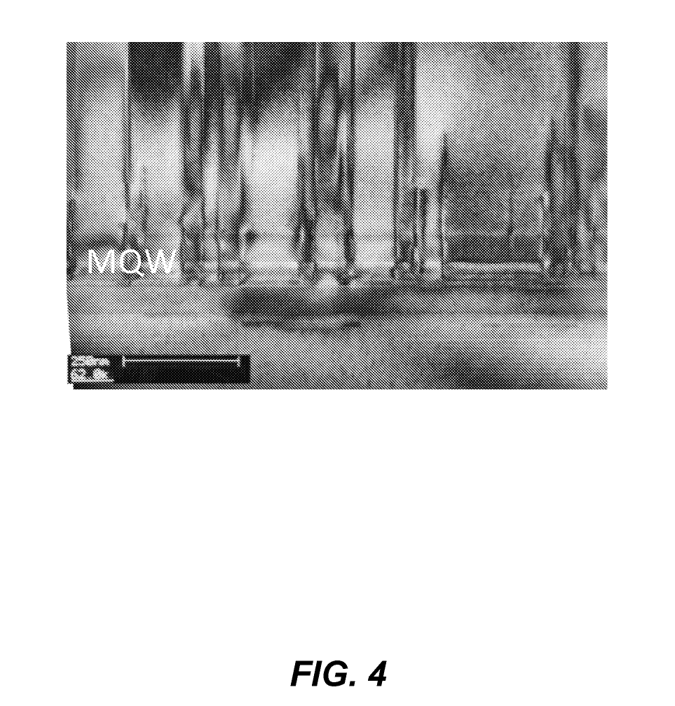

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Device Structure and Fabrication Method

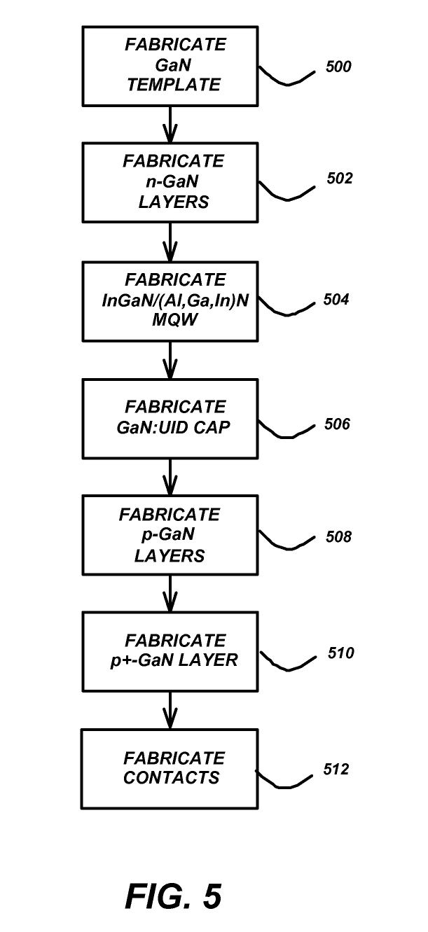

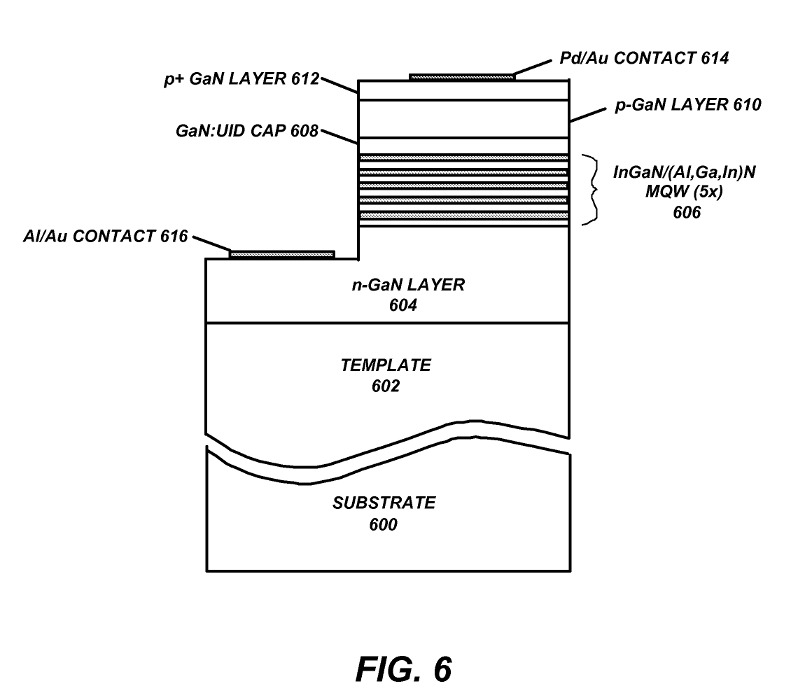

FIG. 5 is a flowchart describing the process steps for fabrication of a nonpolar, semipolar or polar (Al,Ga,In)N light emitting device according to the preferred embodiment of the present invention, while FIG. 6 is a schematic cross-section of a light emitting device fabricated in FIG. 5 according to the preferred embodiment of the present invention.

Block 500 represents the fabrication of a smooth, low-defect-density template on a substrate. For example, this Block may represent the fabrication, on an r-plane sapphire substrate 600, of a GaN template 602.

Block 502 represents the fabrication of an n-GaN base layer 604.

Block 504 represents the fabrication of an active region 606 for the device. In this embodiment, the active region 606 is comprised of a multiple quantum well (MQW) stack comprised of multiple InGaN quantum well layers, wherein each of the InGaN quantum well layers is sandwiched between at least two (Al,Ga,In)N barrier layers.

Block 506 represents the fabrication of an undoped GaN barrier 608 to cap the InGaN/(Al,Ga,In)N MQW structure 606, in order to prevent desorption of In in later steps.

Block 508 represents the fabrication of one or more p-type (Al,Ga)N layers 610 on the undoped GaN barrier 608.

Block 510 represents the fabrication of a heavily doped p⁺-GaN layer 612, which acts as a cap for the structure.

Finally, Block 512 represents the fabrication of a Pd/Au contact 614 and an Al/Au contact 616, as p-GaN and n-GaN contacts, respectively, for the device.

The end result of these process steps is a nonpolar, semipolar or polar (Al,Ga,In)N light emitting device.

Note that this process and the resulting structure are merely exemplary and should not be considered limiting in any way. For example, other embodiments within the scope of this invention may not include these specific steps or layers, and may include other and different steps and layers.

Coupled Quantum Wells

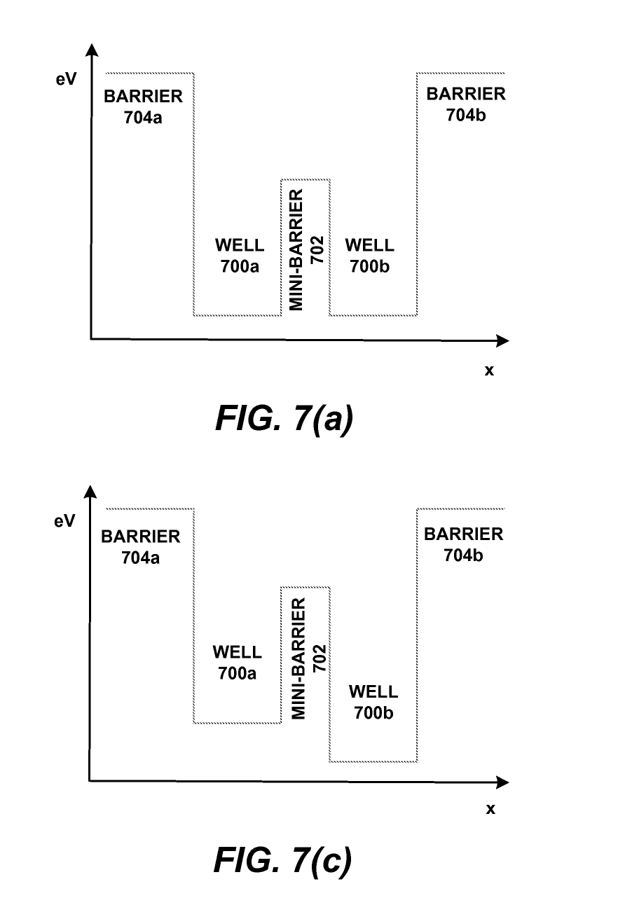

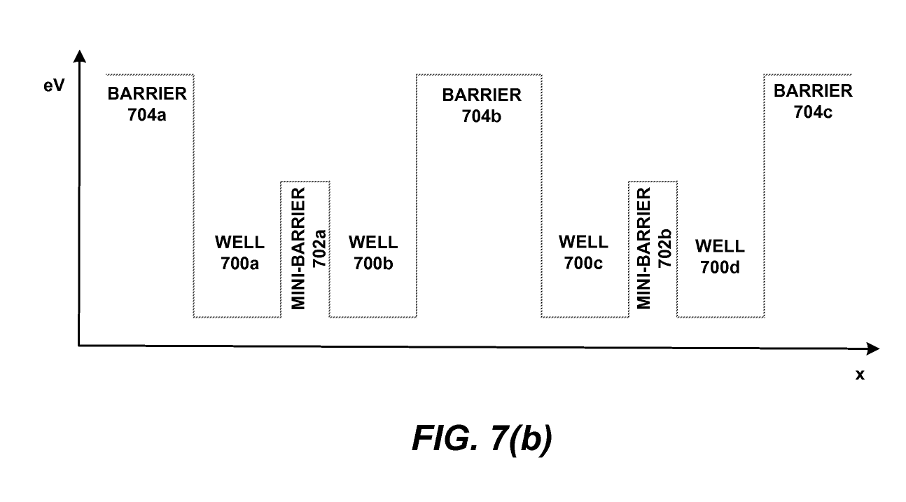

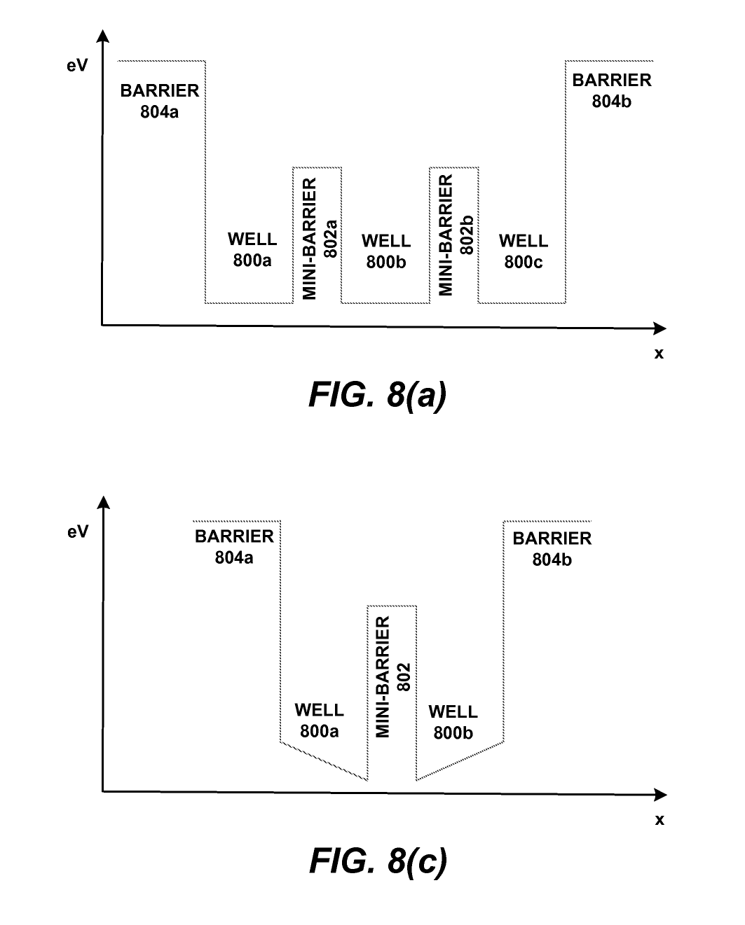

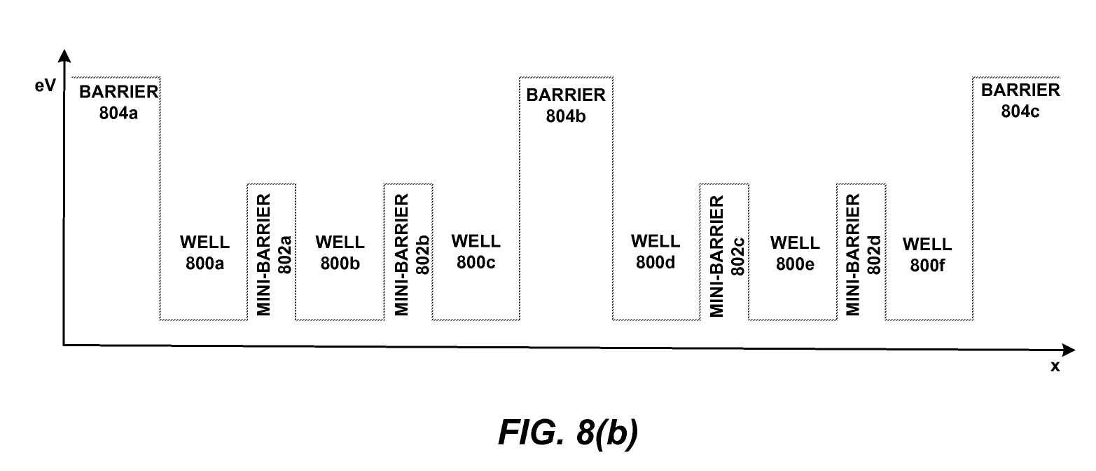

The present invention describes a coupled quantum well structure using a number of different variations in the material composition of the layers found in the InGaN/(Al,Ga,In)N MQW structure 606. These variations are schematically illustrated by FIGS. 7(a)-7(c), 8(a)-(c), and 9(a)-9(b), which are graphs of the potential energy function for a coupled quantum well structure formed by at least one InGaN quantum well layer sandwiched between at least two (Al,Ga,In)N barrier layers in the MQW structure 606.

Generally, the coupled quantum well structure has a material composition that creates an energy diagram comprising: (1) at least two potential wells that are quantum wells bounded by potential barriers, and (2) one or more potential mini-barriers between the potential wells. Specifically, the material composition of the potential wells comprises InₓGa₁₋ₓN, the material composition of the potential mini-barriers comprises In_{y}Ga_{1-y}N where y<x, and the material composition of the potential barriers comprises AlGaN, GaN, AlInGaN or In_{z}Ga_{1-z}N where z<y. The energy diagram or band structure describes the energy of an electron in the active layer (conduction band), or the energy of holes in the active layer (the valence band), for these material compositions.

In the energy diagram, the potential wells are different from the potential mini-barriers, and the potential barriers are different from both the potential wells and the potential mini-barriers. Specifically, the potential wells, the potential mini-barriers and the potential barriers represent one or more abrupt or gradual differences in energy between positions in the energy band structure. As a result, the potential energy increases from a potential minimum at the bottom of the wells to a potential maximum at the top of the barriers bounding the wells and mini-barriers.

According to one embodiment of the present invention, the coupled quantum well structure may have a material composition that creates an energy diagram comprising:

(i) a first one of the potential barriers;

(ii) a first one of the potential wells;

(iii) a potential mini-barrier;

(iv) a second one of the potential wells; and

(v) a second one of the potential barriers.

In addition, where the potential mini-barrier is a first potential mini-barrier, the coupled quantum well structure may have a material composition that creates an energy diagram further comprising (1) a second potential mini-barrier and (2) a third potential well, between the second potential well and the second potential barrier. Alternatively, the second potential mini-barrier and the third potential well may be between the first potential barrier and the first potential well.

From these general embodiments, the various embodiments shown in FIGS. 7(a)-7(c), 8(a)-(c), and 9(a)-9(b) may be derived. However, these embodiments are merely exemplary and are not intended to be exhaustive. Specifically, many variations are possible, including coupled quantum well structures with additional and different layers, wells, mini-barriers and barriers.

FIG. 7(a) schematically illustrates a single mini-barrier coupled quantum well structure, by means of graphs of the potential energy function. The single mini-barrier coupled quantum well structure comprises two square potential wells 700a, 700b separated by a potential mini-barrier 702. The potential wells 700a, 700b and the potential mini-barrier 702 are sandwiched between first and second potential barriers 704a, 704b.

FIG. 7(b) schematically illustrates a double mini-barrier coupled quantum well structure, by means of graphs of the potential energy function. In this figure, there are, from left to right (n-side of the device to p-side of the device), potential barrier 704a, potential well 700a, potential mini-barrier 702a, potential well 700b, potential barrier 704b, potential well 700c, potential mini-barrier 702b, potential well 700d and potential barrier 704c.

FIG. 7(c) schematically illustrates a single mini-barrier coupled quantum well structure, by means of graphs of the potential energy function. In this figure, the single mini-barrier coupled quantum well structure comprises two square potential wells 700a, 700b separated by a potential mini-barrier 702, wherein the two square potential wells 700a, 700b exhibit different potential energies.

FIG. 8(a) schematically illustrates a double mini-barrier coupled quantum well structure, by means of graphs of the potential energy function. The double mini-barrier coupled quantum well structure comprises three square potential wells 800a, 800b, 800c separated by two potential mini-barriers 802a, 802b. The potential wells 800a, 800b, 800c and the potential mini-barriers 802a, 802b are sandwiched between first and second potential barriers 804a, 804b.

FIG. 8(b) schematically illustrates a quadruple mini-barrier coupled quantum well structure, by means of graphs of the potential energy function. In this figure, there are, from left to right (n-side of the device to p-side of the device), potential barrier 804a, potential well 800a, potential mini-barrier 802a, potential well 800b, potential mini-barrier 802b, potential well 800c, potential barrier 804b, potential well 800d, potential mini-barrier 802c, potential well 800e, potential mini-barrier 802d, potential well 800f, and potential barrier 804c.

FIG. 8(c) schematically illustrates a single mini-barrier coupled quantum well structure, by means of graphs of the potential energy function. In this figure, the single mini-barrier coupled quantum well structure comprises two graded potential wells 800a, 800b separated by a potential mini-barrier 802 and bounded by potential barriers 804a, 804b, wherein the two graded potential wells 800a, 800b exhibit different potential energies.

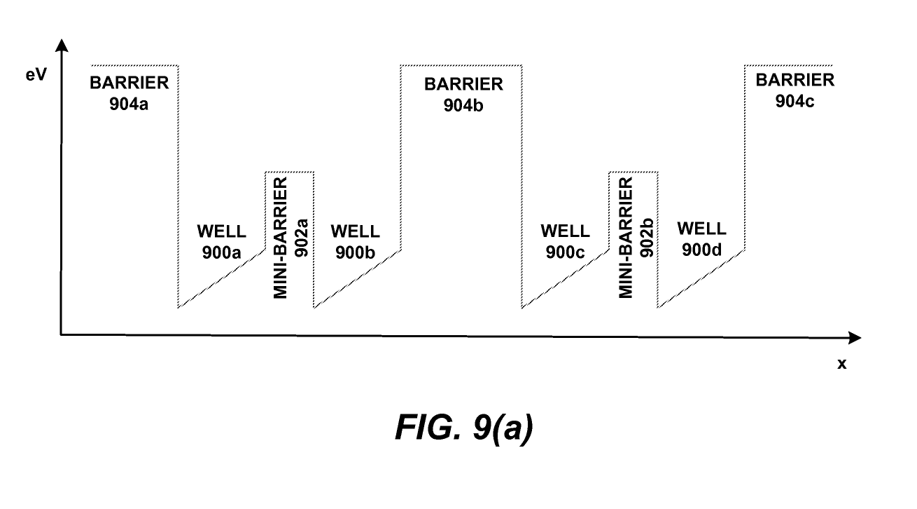

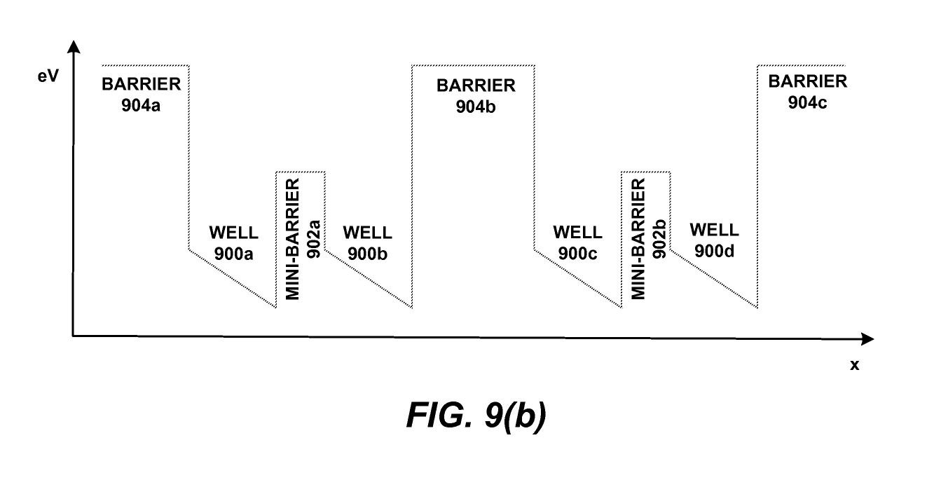

FIG. 9(a) schematically illustrates a double mini-barrier coupled quantum well structure, by means of graphs of the potential energy function. The double mini-barrier coupled quantum well structure comprises four graded potential wells 900a, 900b, 900c, 900d separated by two potential mini-barriers 902a, 902b. The potential wells 900a, 900b, 900c, 900d and the potential mini-barriers 902a, 902b are sandwiched between first, second and third potential barriers 904a, 904b, 904c.

FIG. 9(b) schematically illustrates a double mini-barrier coupled quantum well structure, by means of graphs of the potential energy function. The double mini-barrier coupled quantum well structure comprises four graded potential wells 900a, 900b, 900c, 900d separated by two potential mini-barriers 902a, 902b. The potential wells 900a, 900b, 900c, 900d and the potential mini-barriers 902a, 902b are sandwiched between first, second and third potential barriers 904a, 904b, 904c.

Note that the difference between FIGS. 9(a) and 9(b) is the direction of the grade in the potential wells 900a, 900b, 900c, 900d.

Possible Modifications

There may be various embodiments of the present invention. For example, the following variations are possible:

1. Generally, a simple single coupled quantum well structure (as shown in FIGS. 7(a) and 7(b)), has a primary well, which is comprised of two square InₓGa₁₋ₓN wells with an In composition of x, and a thin In_{y}Ga_{1-y}N mini-barrier inside the well with an In composition of y, where y<x. As noted above, the barriers can be AlGaN, GaN, AlInGaN or In_{z}Ga_{1-z}N where z<y.

2. The thin mini-barrier may be evenly placed or positioned inside the primary well, such that the opposite wells have the same width. However, the position of the mini-barrier may not be evenly placed inside the primary well, and the opposite wells may have different thicknesses.

3. There may be one mini-barrier, as shown in FIG. 7(a), or multiple mini-barriers, as shown in FIG. 8(a). The pattern of wells and mini-barriers can be repeated, as shown in FIGS. 7(b) and 8(b).

4. The wells may be square or triangular (graded) wells, as shown in FIGS. 9(a) and 9(b). The wells may have other shapes as well.

5. The bandgap of two wells (determined by the composition of the AlGaInN alloy) connected by a mini-barrier could be different, as shown in FIG. 7(c).

6. Two graded quantum wells coupled by a mini-barrier could have different directions of grading, as shown in FIG. 8(c). Alternatively, two graded quantum wells coupled by a mini-barrier could have the same grading directions, as shown in FIGS. 9(a) and 9(b). In addition, the gradings may be linear or non-linear.

7. The present invention can be applied to polar, nonpolar, and semipolar (Al,Ga,In)N light emitting devices.

8. The present invention can be applied to light emitting structures containing AlInGaN barriers within the active region.

9. The present invention can be applied to light emitting structures containing InGaN as the primary quantum well.

10. The light emitting device can be a laser, light-emitting diode, etc.

11. The present invention can be applied to devices emitting any wavelength of light, ranging from ultraviolet (UV) to the yellow spectral range.

Effectiveness of the Coupled Quantum Well Structure

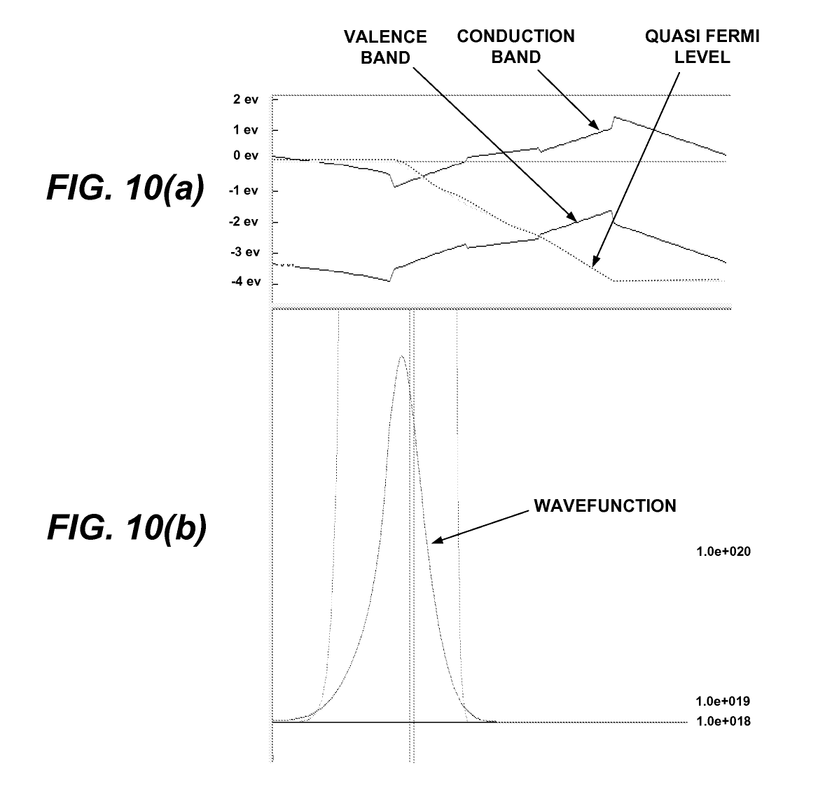

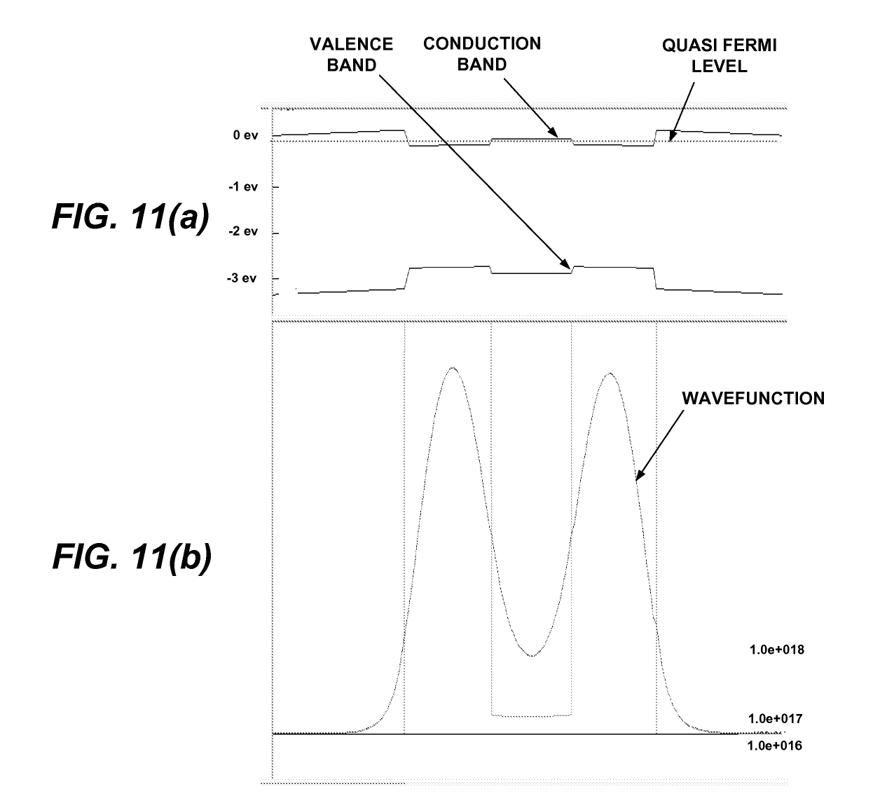

FIGS. 10(a), 10(b), 11(a), and 11(b) are graphs of simulated data supporting the assertion that nonpolar coupled quantum well structures are more effective than polar coupled quantum well structures.

FIGS. 10(a) and 10(b) illustrate the ineffectiveness of a coupled quantum well in the polar (Al,Ga,In)N materials system. For example, FIG. 10(a) shows an energy band diagram of a quantum well structure comprised of: 100 Å GaN barrier, 30 Å In_{0.3}Ga_{0.7}N well, 30 Å In_{0.2}Ga_{0.7}N mini-barrier, 30 Å In_{0.3}Ga_{0.7}N well, and 100 Å GaN barrier. Specifically, in FIG. 10(a), the conduction band, valence band, and the quasi-Fermi level (dashed line) are indicated. FIG. 10(b) shows the electron wavefunction in the polar coupled quantum well system shown in FIG. 10(a), wherein the indicated electron wavefunction is situated at one end of the quantum well stack and therefore the overlap with the hole wavefunction is almost negligible.

FIGS. 11(a) and 11(b) illustrate the effectiveness of a coupled quantum well in the nonpolar (Al,Ga,In)N materials system. For example, FIG. 11(a) shows an energy band diagram of a quantum well structure comprised of: 100 Å GaN barrier, 30 Å In_{0.3}Ga_{0.7}N well, 30 Å In_{0.2}Ga_{0.7}N mini-barrier, 30 Å In_{0.3}Ga_{0.7}N well, and 100 Å GaN barrier. Specifically, in FIG. 11(a), the conduction band, valence band, and the quasi-Fermi level (dashed line) are indicated. FIG. 11(b) shows the electron wavefunction in the nonpolar coupled quantum well system shown in FIG. 11(a), wherein the indicated electron wavefunction is symmetrically situated across the quantum well stack and therefore there is a perfect overlap with the hole wavefunction. Furthermore, the wavefunctions in the two quantum wells are coupled through the mini-barrier.

Advantages and Improvements

This invention has the following advantages compared to the prior art:

1. In one embodiment, the coupled quantum well is used in a blue-green-yellow light emitting (Al,Ga,In)N based light emitting device. The impact of the coupled quantum well is higher for quantum wells with high In composition.

2. The use of coupled quantum wells with a thin mini-barrier inside the primary well allows strain relief, because several thin wells can be combined as a primary well instead of using s thick high In composition well.

3. The use of a coupled quantum well structure also reduces quantum confinement, resulting in lowering of the ground state energy level. This allows longer wavelength emission from a lower In composition primary well.

4. The coupled quantum well also allows tunneling of carriers through the mini barriers, resulting in improved carrier capture and radiative efficiency.

5. The coupled quantum well prevents In segregation in the quantum well.

Nomenclature

The terms (Al,Ga,In)N, III-nitride, Group III-nitride, nitride, Al_{(1-x-y)} GaₓIn_{y}N where 0<x<1 and 0<y<1, or AlInGaN, as used herein are intended to be broadly construed to include respective nitrides of the single species, Al, Ga and In, as well as binary, ternary and quaternary compositions of such Group III metal species. Accordingly, the term (Al,Ga,In)N comprehends the compounds AlN, GaN, and InN, as well as the ternary compounds AlGaN, GaInN, and AlInN, and the quaternary compound AlGaInN, as species included in such nomenclature. Accordingly, it will be appreciated that the discussion of the invention hereinafter in reference to specific (Al,Ga,In)N materials, such as GaN or InGaN, is applicable to the formation of various other species of these (Al,Ga,In)N materials. Further, (Al,Ga,In)N materials within the scope of the invention may further include minor quantities of dopants and/or other impurity or inclusional materials.

(Al,Ga,In)N optoelectronic and electronic devices are typically grown on c-plane sapphire substrates, SiC substrates or bulk (Al,Ga,In)N substrates. In each instance, the devices are usually grown along their polar (0001) c-axis orientation, i.e., a c-plane direction.

However, conventional polar (Al,Ga,In)N based devices suffer from undesirable quantum-confined Stark effect (QCSE), due to the existence of strong piezoelectric and spontaneous polarizations. For example, GaN and its alloys are the most stable in a hexagonal würtzite crystal structure, in which the structure is described by two (or three) equivalent basal plane axes that are rotated 120° with respect to each other (the a-axis), all of which are perpendicular to a unique c-axis. Group III atoms, such as Ga, and N atoms occupy alternating c-planes along the crystal's c-axis. The symmetry elements included in the würtzite structure dictate that (Al,Ga,In)N devices possess a bulk spontaneous polarization along this c-axis, and the würtzite structure exhibits piezoelectric polarization, which give rise to restricted carrier recombination efficiency, reduced oscillator strength, and red-shifted emission.

One approach to eliminating the spontaneous and piezoelectric polarization effects in (Al,Ga,In)N devices is to grow the devices on nonpolar planes of the crystal, which are orthogonal to the c-plane of the crystal. For example, with regard to GaN, such planes contain equal numbers of Ga and N atoms, and are charge-neutral. Furthermore, subsequent nonpolar layers are crystallographically equivalent to one another, so the crystal will not be polarized along the growth direction. Two such families of symmetry-equivalent nonpolar planes in GaN are the {11-20} family, known collectively as a-planes, and the {1-100} family, known collectively as m-planes.

Another approach to reducing or possibly eliminating the polarization effects in GaN optoelectronic devices is to grow the devices on semipolar planes of the crystal. The term semipolar planes can be used to refer to a wide variety of planes that possess two nonzero h, i, or k Miller indices, and a nonzero 1 Miller index. Some examples of semipolar planes in the würtzite crystal structure include, but are not limited to, {10-12}, {20-21}, and {10-14}. The crystal's polarization vector lies neither within such planes or normal to such planes, but rather lies at some angle inclined relative to the plane's surface normal.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting device, comprising:
an (Al,Ga,In)N based active region including at least one coupled quantum well structure formed by at least one (Al,Ga,In)N based quantum well layer sandwiched between at least first and second (Al,Ga,In)N based barrier layers;
wherein the coupled quantum well structure has a material composition that creates an energy diagram comprising:
(1) at least two potential wells bounded by potential barriers, and
(2) at least one potential mini-barrier between the two potential wells.

2. The device of claim 1, wherein the potential well is different from the potential mini-barrier, and the potential barriers are different from both the potential well and the potential mini-barriers.

3. The device of claim 1, wherein the coupled quantum well structure has a material composition that creates an energy diagram comprising:
(i) a first one of the potential barriers;
(ii) a first one of the potential wells;
(iii) a first one of the potential mini-barriers;
(iv) a second one of the potential wells; and
(v) a second one of the potential barriers.

4. The device of claim 3, wherein the coupled quantum well structure has a material composition that creates an energy diagram further comprising:
a second one of the potential mini-barriers and a third one of the potential wells, positioned between the second one of the potential wells and the second one of the potential barriers.

5. The device of claim 3, wherein the coupled quantum well structure has a material composition that creates an energy diagram further comprising:
a second one of the potential mini-barriers and a third one of the potential wells, positioned between the first one of the potential barriers and the first one of the potential wells.

6. The device of claim 1, wherein the material composition of the potential well is InₓGa₁₋ₓN, and the material composition of the potential mini-barrier is In_{y}Ga_{1-y}N, where y<x.

7. The device of claim 6, wherein the material composition of the potential barriers is AlGaN, GaN, AlInGaN or In_{z}Ga_{1-z}N where z<y.

8. The device of claim 1, wherein the material composition comprises a polar, nonpolar or semipolar (Al,Ga,In)N based material composition.

9. A method for fabricating a light emitting device, comprising:
fabricating an (Al,Ga,In)N based active region including at least one coupled quantum well structure formed by at least one (Al,Ga,In)N based quantum well layer sandwiched between at least first and second (Al,Ga,In)N based barrier layers;
wherein the coupled quantum well structure has a material composition that creates an energy diagram comprising:
(1) at least two potential wells bounded by potential barriers, and
(2) at least one potential mini-barrier between the two potential wells.

10. The method of claim 9, wherein the potential well is different from the potential mini-barrier, and the potential barriers are different from both the potential well and the potential mini-barriers.

11. The method of claim 9, wherein the coupled quantum well structure has a material composition that creates an energy diagram comprising:
(i) a first one of the potential barriers;
(ii) a first one of the potential wells;
(iii) a first one of the potential mini-barriers;
(iv) a second one of the potential wells; and
(v) a second one of the potential barriers.

12. The method of claim 11, wherein the coupled quantum well structure has a material composition that creates an energy diagram further comprising:
a second one of the potential mini-barriers and a third one of the potential wells, positioned between the second one of the potential wells and the second one of the potential barriers.

13. The method of claim 11, wherein the coupled quantum well structure has a material composition that creates an energy diagram further comprising:
a second one of the potential mini-barriers and a third one of the potential wells, positioned between the first one of the potential barriers and the first one of the potential wells.

14. The method of claim 9, wherein the material composition of the potential well is InₓGa₁₋ₓN, and the material composition of the potential mini-barrier is In_{y}Ga_{1-y}N, where y<x.

15. The method of claim 14, wherein the material composition of the potential barriers is AlGaN, GaN, AlInGaN or In_{z}Ga_{1-z}N where z<y.

16. The method of claim 9, wherein the material composition comprises a polar, nonpolar or semipolar (Al,Ga,In)N based material composition.
